(19) United States
(12) Patent Application Publication
(10) Pub. No.: US 2001/0018258 A1
(43) Pub. Date: Aug. 30, 2001

(54) Method for fabricating semiconductor device

(76) Inventor: Kyeong Yoon III, Kyoungki-do (KR)

Correspondence Address: Pillisbury Madison & Sutro LLP, Intellectual Property Group, Ninth Floor, East Tower, 1100 New York Avenue, NW., Washington, DC, 20005-3918, US

(21) Appl. No.: 09/751,400

(22) Filed: Jan. 2, 2001

(30) Foreign Application Priority Data
Dec. 30, 1999 (KR) 1999-67061

(51) Int. Cl. H01L 21/26; H01L 21/42; H01L 21/336; H01L 21/04; H01L 21/425

(52) U.S. Cl. 438/530; 438/510; 438/535

(57) ABSTRACT

The present invention discloses a method for fabricating a semiconductor device which can form a MOSFET device according to a laser doping method. When junctions of the MOSFET device are formed, the MOSFET device has various junction depths by region, by using a doping difference according to the heat and time of a laser irradiation process. As compared with a two-dimensional method for controlling a property of the transistor by a channel width and length, the present invention provides a method for exercising three-dimensional control over the formation of transistors and other junctions in a semiconductor device.

### BACKGROUND OF THE INVENTION

1. Field of the Invention

The present invention relates to a method for fabricating a semiconductor device and, in particular, to an improved method for fabricating a semiconductor device which can have junctions of various depths, including shallow junctions, through use of a laser doping method.

2. Description of the Background Art

As a result of the increasingly high integration levels of advanced semiconductor devices, it has become necessary to form junctions having various depths, including shallow junctions on a single semiconductor device.

In a conventional method, junctions are formed by using a photoresist film pattern on a semiconductor substrate as an implant mask, and implanting impurity ions into selected regions of the substrate.

With this method however, the junctions are formed a substantially identical depth into the semiconductor substrate, and thus have substantially identical electrical properties.

Accordingly, there is a need for additional processes in order to form junctions having various depths on one substrate. Another concern is the tendency for the implanted impurities to diffuse during subsequent processing, thereby generating short channel effects in the resulting transistors. As a result, it remains difficult to produce highly integrated semiconductor devices.

### SUMMARY OF THE INVENTION

Therefore, it is an object of the present invention to provide a method for fabricating a semiconductor device that can produce junctions in different regions having different properties forming junctions of various depths with a laser annealing process.

In order to achieve the above-described object of the present invention, a method for fabricating a semiconductor device includes the steps of: melting a surface of a semiconductor substrate by performing a thermal treatment thereon; stacking a specific type impurity on the surface of the semiconductor substrate; and doping the substrate by melting the impurity on the surface of the semiconductor substrate using laser radiation in the intended junction regions of the semiconductor substrate.

### BRIEF DESCRIPTION OF THE DRAWINGS

The present invention will become better understood with reference to the accompanying drawings which are given only by way of illustration:

FIGS. 1A and 1B are cross-sectional diagrams illustrating a process for forming junctions in accordance with a preferred embodiment of the present invention.

### DETAILED DESCRIPTION OF THE PREFERRED EMBODIMENTS

A method for fabricating a semiconductor device in accordance with the present invention will now be described in detail with reference to the accompanying drawings.

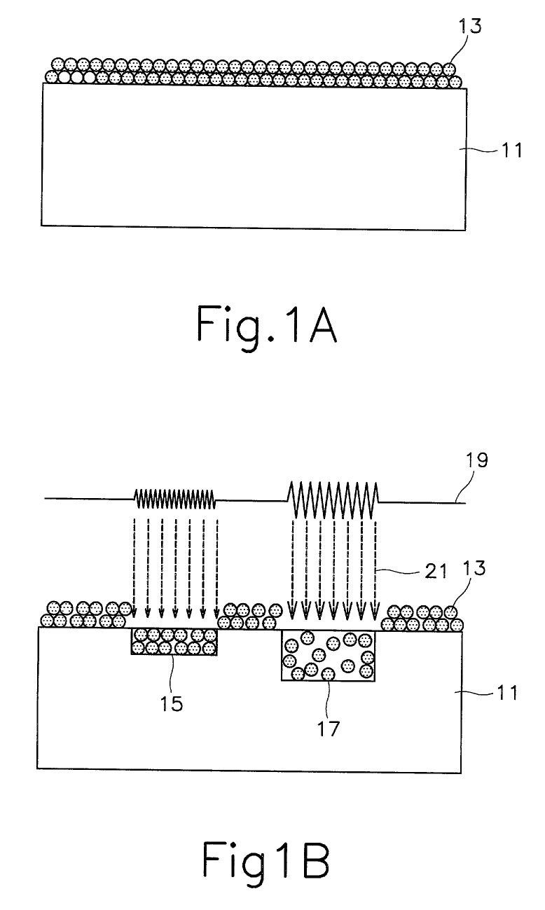

As depicted in FIG. 1A, a predetermined conductive type impurity layer 13 is formed on the whole surface of a semiconductor substrate 11.

In this case, the impurity layer 13 is formed by depositing a polysilicon layer that is doped with a junction type impurity.

Further, the amount of the impurity of the impurity layer 13 is determined according to the desired junction properties in consideration of the doping profile that will result from the laser irradiation of the impurity layer.

As illustrated in FIG. 1B, the impurity is melted onto the surface of the semiconductor substrate 11, by performing a pre-laser thermal treatment on the semiconductor substrate. The purpose of this melting is to make it easy to diffuse the dopant into the substrate. That is, if the substrate is melted before adding the dopant layer, the molecular structure of substrate is broken and much depletion region, which makes diffusion of the dopant into the substrate easy, are formed. This allows a junction having a sufficient depth to be formed by the subsequent process.

Thereafter, the intended junction region of the semiconductor substrate 11 are subjected to laser irradiation 21, to melt a narrowband of semiconductor substrate 11, thereby allowing the impurity ions to diffuse into the substrate and performing a local doping process.

In this local doping process, the resulting dopant profile is dependent upon both heat and time. Therefore, both the energy and duration of the laser irradiation 21 are differentially controlled for each region of the substrate, thereby forming junctions having various predetermined depths. The energy of the laser irradiation is preferably in the range of from 10 K eV to 100 M eV, and duration of the laser irradiation is preferably in the range of from 0.1 seconds to 100 minutes.

When the respective junctions have different depths, the resulting junction diodes have different properties. Reference numerals 15 and 17 denote a shallow junction and a deep junction, respectively.

The laser irradiation process exposes only the intended junction regions of the substrate by using chip pattern layout coordinates or a mask.

An oxide film (not shown) is then formed by oxidizing and consuming the residual impurity layer 13 on the semiconductor substrate 11. The oxide film and the incorporated impurities are then removed via a wet or dry etch process.

As described above, the present invention provides a method for forming a MOSFET device having various preferred junction depths in different regions of the device. This result is achieved with doping differences resulting from adjustments to the energy and duration of the laser irradiation process and the doping level provided at the substrate surface. Moreover, it is possible to control a junction depth of a source/drain various transistors according to their intended purpose. Compared with the prior art two-dimensional method for controlling the properties of the transistor by adjusting channel width and length, the present invention allows the transistors to be formed with three-dimensional control, thereby improving the yield and reliability of the resulting semiconductor device.

As the present invention may be embodied in several forms without departing from the spirit or essential characteristics thereof, it should also be understood that the above-described embodiment is not limited to the details of the foregoing description, unless otherwise specified, but rather should be construed broadly within its spirit and scope as defined in the appended claims, and therefore all changes and modifications that fall within the metes and bounds of the claims, or equivalencies of such metes and bounds are therefore intended to be embraced by the appended claims.

What is claimed is:

1. A method for fabricating a semiconductor device, comprising the steps of:
melting a surface of a semiconductor substrate by performing a thermal treatment thereon; stacking a specific type impurity on the surface of the semiconductor substrate; and
performing a doping process by melting the impurity on the semiconductor substrate by irradiating a laser into a presumed junction region of the semiconductor substrate, a junction depth being varied by controlling an energy and irradiation time of the laser.

2. The method according to claim 1, wherein, in the laser irradiation process, the laser is irradiated merely into the presumed junction region, by using chip pattern layout coordinates.

3. The method according to claim 1, wherein, in the laser irradiation process, the laser is irradiated merely into the presumed junction region by using a mask.

4. The method according to claim 1, wherein a property of junction diodes is controlled by locally differentially controlling an amount of the impurity to be stacked on the semiconductor substrate.

5. A method of fabricating a semiconductor device, comprising the steps of:
forming a semiconductor substrate;
forming a layer of conductive material on the surface of the semiconductor substrate, the conductive material containing a concentration of dopant atoms;
diffusing the dopant atoms into predetermined regions of the semiconductor substrate to form junction regions, each junction region being characterized by a junction depth, by exposing the semiconductor substrate to laser irradiation of predetermined energy and duration; and
controlling the junction depth by one or more methods selected from the group consisting of
adjusting the concentration of dopant atoms in the conductive material,
controlling the thickness of the layer of conductive material,
controlling the energy of the laser irradiation, and
controlling the duration of the laser irradiation.

6. The method according to claim 5, wherein only the predetermined regions of the semiconductor substrate are exposed to the laser irradiation process.

7. The method according to claim 6, wherein the predetermined regions exposed to the laser irradiation are selected from chip pattern layout coordinates.

8. The method according to claim 6, wherein the predetermined regions exposed to the laser irradiation are determined by a mask that prevents the laser illumination from reaching regions of the semiconductor substrate other than the predetermined regions.

9. The method according to claim 5, wherein at least first and second junction regions are formed in the semiconductor substrate,
the first and second junction regions being characterized by first and second junction depths, the first and second junction depths being different; and
the first and second junction regions being further characterized by first and second junction diode properties, the first and second junction diode properties being different.

10. The method according to claims 5 or 9 wherein the step of controlling junction depth is accomplished by one or more methods selected from the group consisting of
forming a barrier layer pattern between the semiconductor substrate and the conductive material,
adjusting the concentration of dopant atoms in the conductive material,
adjusting the thickness of the layer of conductive material,
adjusting the energy of the laser irradiation, and
adjusting the duration of the laser irradiation.
